(19) United States
(12) Patent Application Publication
(10) Pub. No.: US 2024/0242928 A1
(43) Pub. Date: Jul. 18, 2024

(54) Charged Particle Beam Device and Method for Controlling Same

(71) Applicant: Hitachi High-Tech Corporation, Minato-ku, Tokyo (JP)

(72) Inventor: Koichi KURODA, Tokyo (JP)

(21) Appl. No.: 18/562,653

(22) PCT Filed: Jun. 25, 2021
(86) PCT No.: PCT/JP2021/024213

§ 371 Date: Nov. 20, 2023

(51) Int. Cl. H01J 37/22; G06T 7/00

(52) U.S. Cl. CPC H01J 37/222; G06T 7/97; H01J 2237/216

(57) ABSTRACT

Provided is a charged particle beam device that makes it possible to perform a high-speed autofocus operation which reduces damage to a sample by eliminating the need for a focus sweep operation or reducing the number of focus sweep operations. A charged particle beam device according to the present invention comprises: a charged particle beam optical system that converges/polarizes a charged particle beam and irradiates a sample with the charged particle beam; an image generation processing unit that generates an image of the sample by detecting the charged particle beam; a storage unit that stores a relation between the focus position of the charged particle beam by the charged particle beam optical system and a feature of the image of the sample; a comparison operation unit that determines the shift amount and the shift direction of the focus position of the charged particle beam by comparing information obtained from the image generated by the image generation processing unit and information in the storage unit; and a control unit that controls the charged particle beam optical system according to a comparison result of the comparison operation unit.

### TECHNICAL FIELD

The present invention relates to a charged particle beam device and a method for controlling the same.

### BACKGROUND ART

In an SEM imaging device for semiconductor process control, image adjustment (autofocus, optic axis adjustment, and the like) before imaging is performed at a high frequency to ensure reproducibility and stability in measurement inspection. Here, by sweeping a focus point on a sample by an operation of a focusing lens, a focusing condition that maximizes a sharpness of an image can be obtained as an optimum focus point.

Here, since an electromagnetic lens is mainly used for the focusing lens, the sweep operation takes a long time due to factors such as power supply and magnetic response, and the time is on the order of several to ten times longer than the time required for the imaging itself. On the other hand, for example, PTL 1 discloses that an electrostatic lens capable of performing autofocusing using a deceleration electric field generated by a retarding voltage is used for performing an autofocus operation at high speed instead of the slow-response electromagnetic lens.

However, when performing autofocusing using a deceleration electric field by retarding voltage as in PTL 1, the power supply required for autofocusing needs to have a circuit configuration for high-speed response. Here, there is the problem that such a power supply is likely to be a source of noise for a SEM image and may cause deterioration of an image quality.

When the retarding voltage changes, a divergence angle and an incident energy of an irradiation beam also change accordingly. Here, the image quality may be destabilized due to differences in an irradiation beam diameter, a type of signal electrons generated from the sample, yield, and a generation distribution. In an operation of a detection system, when the retarding voltage is superimposed on a kinetic energy of signal electrons, since a change in detection rate occurs according to the kinetic energy of the signal electrons, image quality deterioration such as a decrease in SN ratio and a decrease in contrast may occur.

Even in the autofocus operation using the electrostatic lens, a voltage sweep operation for searching for an excitation value that maximizes sharpness is indispensable in the processing flow for accurately obtaining the optimum focus point. Therefore, a considerable amount of time is required for sample imaging and calculation process. Since the sample is continuously irradiated with a charged particle beam during the sweep operation, there is also a problem that contamination of the sample and electrification damage increase.

### CITATION LIST

### Patent Literature

PTL 1: JP2019-204618A

### SUMMARY OF INVENTION

### Technical Problem

The present invention provides a charged particle beam device that makes it possible to perform a high-speed autofocus operation which reduces damage to a sample by eliminating the need for a focus sweep operation or reducing the number of focus sweep operations.

### Solution to Problem

A charged particle beam device according to the present disclosure may include a charged particle beam optical system that converges/polarizes a charged particle beam and irradiates a sample with the charged particle beam, an image generation processing unit that generates an image of the sample by detecting the charged particle beam,

a storage unit that stores a relation between a focus position of the charged particle beam by the charged particle beam optical system and a feature of the image of the sample, a comparison operation unit that determines a shift amount and a shift direction of the focus position of the charged particle beam by comparing information obtained from the image generated by the image generation processing unit and information in the storage unit, and a control unit that controls the charged particle beam optical system according to a comparison result of the comparison operation unit.

### Advantageous Effects of Invention

According to the present disclosure, it is possible to provide a charged particle beam device that makes it possible to perform a high-speed autofocus operation which reduces damage to a sample by eliminating the need for a focus sweep operation or reducing the number of focus sweep operations.

### BRIEF DESCRIPTION OF DRAWINGS

FIG. 1 is a schematic diagram showing an overall configuration of a charged particle beam device according to a first embodiment.

FIG. 2A shows a high-speed autofocus operation in the first embodiment.

FIG. 2B shows the high-speed autofocus operation in the first embodiment.

FIG. 2C shows the high-speed autofocus operation in the first embodiment.

FIG. 2D is a flowchart provided to explain the high-speed autofocus operation in the first embodiment.

FIGS. 2E to 2G show examples of data stored in a database 15 for the autofocus operation in the charged particle beam device of the first embodiment.

FIG. 3A shows an example of data stored in the database 15 for the autofocus operation in a charged particle beam device of a second embodiment.

FIG. 3B shows a principle of the autofocus operation in the second embodiment.

FIG. 3C is a flowchart provided to explain a high-speed autofocus operation in the second embodiment.

FIGS. 4A to 4E show examples of data stored in the database 15 for astigmatism adjustment in a charged particle beam device of a third embodiment.

FIGS. 4F to 4H show examples of data stored in the database 15 for astigmatism adjustment in the charged particle beam device of the third embodiment.

FIG. 5 is a flowchart provided to explain a high-speed autofocus operation in a fourth embodiment.

FIG. 6 shows a procedure for acquiring sharpness difference data to be stored in the database 15 according to design data in a fifth embodiment.

FIG. 7 shows a procedure for acquiring sharpness difference data to be stored in the database 15 according to an image of an actual sample 12 and design data in a sixth embodiment.

FIG. 8 shows a charged particle beam device according to a seventh embodiment.

FIGS. 9A to 9C show examples of data stored in the database 15 in a charged particle beam device of an eighth embodiment.

FIGS. 10A to 10C show examples of data stored in the database 15 in the charged particle beam device of the eighth embodiment.

### DESCRIPTION OF EMBODIMENTS

Hereinafter, the present embodiment will be described with reference to the accompanying drawings. In the accompanying drawings, functionally identical elements may be identified with the same reference numerals. Note that although the accompanying drawings show embodiments and implementations consistent with the principles of the present disclosure, these are for the purpose of understanding the present disclosure and are in no way used to interpret the present disclosure in a limiting manner. The description of the specification is merely exemplary and is not intended to limit the claims or application example of the present disclosure in any way.

Note that although the present embodiments are described in sufficient detail to enable those skilled in the art to practice the present disclosure, other implementations and embodiments are possible, and that the changes in configuration and structure and substitution of various elements are possible without departing from the scope and spirit of the technical concept of the present disclosure. Therefore, the following description should not be construed as being limited thereto.

### First Embodiment

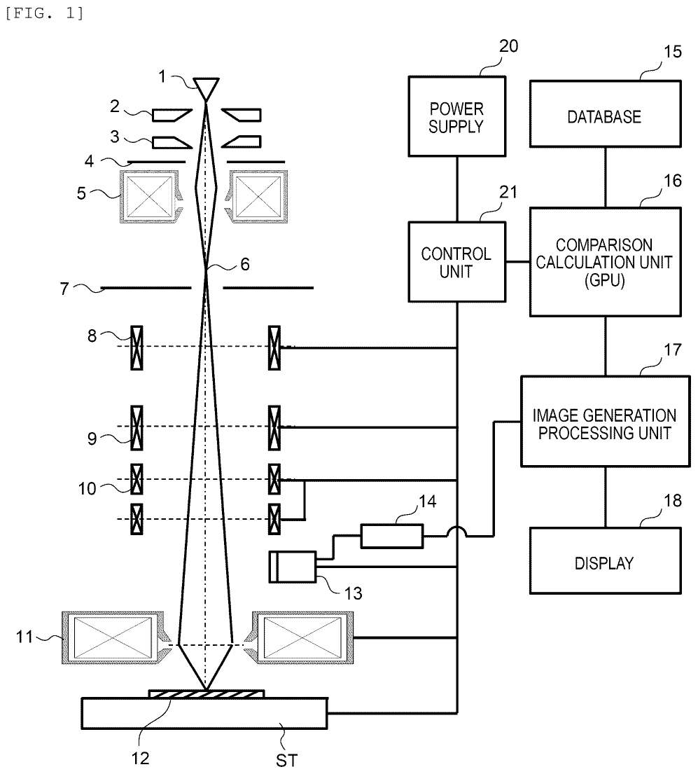

The overall configuration of the charged particle beam device according to the first embodiment will be described with reference to FIG. 1. As an example, the charged particle beam device includes, as an electron beam optical system (charged particle beam optical system), an electron gun 1, extraction electrodes 2 and 3, an anode diaphragm 4, a condenser lens 5, an objective variable diaphragm 7, an astigmatism adjustment coil 8, an optic axis adjustment coil 9, a scanning polarizer 10, and an objective lens 11. The charged particle beam device includes, as a signal processing system, a detector 13, a signal processing unit 14, a database 15, a comparison operation unit 16, an image generation processing unit 17, a display 18, a power supply 20, and a control unit 21.

In the electron beam optical system, electrons emitted from the electron gun 1 are emitted as a primary electron beam 6 by the voltage of the extraction electrodes 2 and 3. The primary electron beam 6 passes through the anode diaphragm 4, the condenser lens 5, the objective variable diaphragm 7, the scanning polarizer 10, the objective lens 11 and the like, is converged/polarized, and irradiated onto a sample 12. The astigmatism and optic axis of the primary electron beam 6 are adjusted by applying voltages to the astigmatism adjustment coil 8 and the optic axis adjustment coil 9. A focus position of the primary electron beam 6 is changed by changing voltages applied to the coils of the condenser lens 5 and the objective lens 11. Voltages applied to the condenser lens 5, the astigmatism adjustment coil 8, the optic axis adjustment coil 9, the scanning polarizer 10, the objective lens 11, the detector 13 and the like are controlled by the control unit 21.

A secondary electron beam is generated from the sample 12 by irradiating the sample 12 with the primary electron beam 6, and the secondary electron beam enters the detector 13. The detector 13 converts the entered secondary electrons into electric signals. The electric signals are amplified by a preamplifier (not shown) and then subjected to a predetermined signal processing at the signal processing unit 14. The electric signals after signal processing are input to the image generation processing unit 17 and subjected to data processing for generating an image of the sample 12.

The image generated by the image generation processing unit 17 and/or various types of data obtained from the image are compared with the image and/or various data stored in the database 15 in the comparison operation unit 16, thereby determining a shift amount and a shift direction between a current focus position and an in-focus position (optimum focus position) of the sample 12. The comparison operation unit 16 can be formed by a well-known graphics processing unit (GPU) or central processing unit (CPU).

The database 15 stores information on the sample 12 to be observed and optical characteristic information on the electron beam optical system (charged particle beam device). The database 15 stores, as information of the sample 12 to be observed, an image of the sample 12, changes in the profile of the image, feature amounts extracted from the image, and the like when the focus position of the primary electron beam 6 changes within a predetermined range from the in-focus position (optimum focus position), for example. In the first embodiment, as an example of the feature amount, information on the difference in sharpness (sharpness difference) in the image of the sample 12 obtained for each focus position is stored in the database 15. The images to be stored in the database 15 may be acquired by actually imaging images of the sample in advance, or may be artificial images acquired by computer simulation using techniques such as deep learning.

In the charged particle beam device according to the first embodiment, when the autofocus operation is performed at high speed, the image of the sample 12 obtained by the image generation processing unit 17 according to the signal of the detector 13 and/or various data obtained from the image are compared with the data of the database 15 by the comparison operation unit 16, thereby calculating the shift amount and the shift direction from the in-focus position. According to the calculated shift amount and shift direction, the control unit 21 controls the condenser lens 5 and the objective lens 11 to perform high-speed autofocus. According to the first embodiment, in the autofocus operation, the so-called focus sweep operation is unnecessary or the number of executions thereof can be reduced, so the autofocus operation can be completed at high speed.

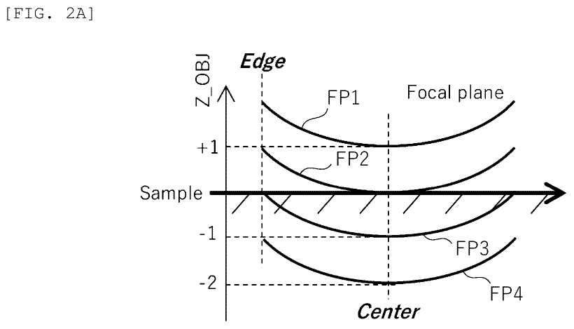

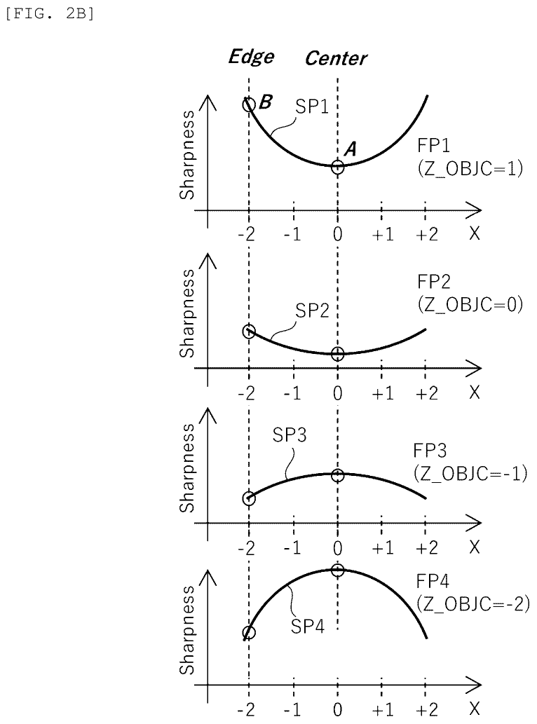

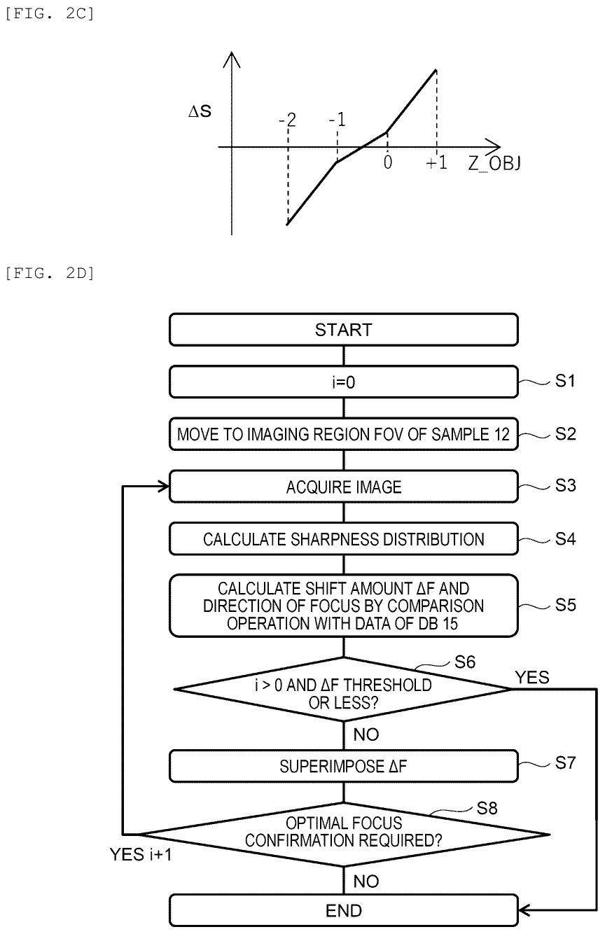

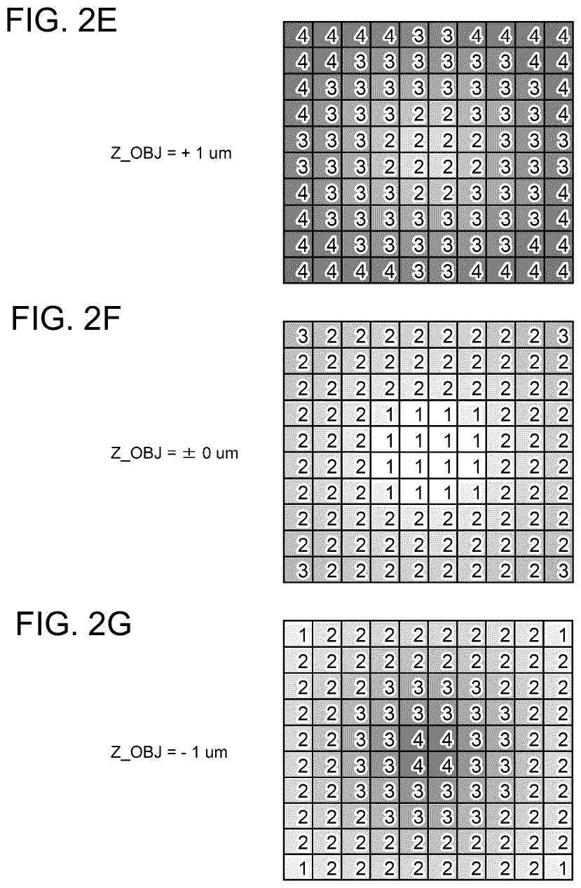

The high-speed autofocus operation in the first embodiment will be described with reference to FIGS. 2A to 2D. Here, an image of the sample 12 is imaged, a sharpness difference in one obtained image is acquired as a feature amount, and the shift amount and the shift direction of the current focus position from the optimum focus position are determined with reference to the database 15 according to the acquired sharpness, thereby performing an autofocus operation. The method based on the sharpness difference is suitable for imaging wide-field images. Generally, when imaging a wide-field image, even when an in-focus state is obtained in the central portion of the imaging region, out-of-focus blur (defocusing) occurs in the outer peripheral portion. The out-of-focus blur is caused by an optical characteristic (aberration) called curvature of field, and is caused by bending the focal plane (focus plane) toward the outer peripheral portion.

FIG. 2A shows changes in the focus position (focal plane) when the focus position is moved by changing the voltage applied to the objective lens 11 and the like. The horizontal axis of the graph in FIG. 2A indicates a horizontal distance of the sample 12, and the vertical axis indicates a distance Z_OBJ between the surface of the sample 12 and the focus position.

Curves FP1 to FP4 in FIG. 2A indicate focal planes, and the focal plane FP moves up and down under the control of the objective lens 11. In the focal planes FP1 to FP4, the distance (Z_OBJ) from the surface of the sample 12 in the height direction differs between the central portion (center) and the outer peripheral portion (edge) of the imaging region FOV (curvature of field). The degree of curvature of field (the degree of bending of the focal plane FP4) also differs between the focal planes FP1 to FP4.

In the focal plane FP1, the focus position including the center of the imaging region FOV is above the surface of the sample 12 (overfocus). From here, as in the focal plane FP2, when the focus position at the center of the imaging region FOV is moved to near the height of the sample 12 (the distance Z_OBJC between the surface position of the sample 12 and the center of the focal plane FP≈0), the in-focus state is obtained at the center. However, even when the focal plane FP2 is obtained and the center of the imaging region FOV is in the in-focus state, the edge of the imaging region FOV cannot be in the in-focus state due to curvature of field.

Then, when the focus position is further lowered from the focal plane FP2 at the center of the imaging region FOV, and the focus position at the center becomes lower than the surface of the sample 12 as in the focal plane FP3 (underfocus), the edge of the imaging region FOV gradually approaches the in-focus state and the image becomes clear, while the central portion of the imaging region FOV moves away from the in-focus state and the degree of blurring of the image gradually increases. As in the focal plane FP4, when the focus position moves further downward than the focal plane FP3, the degree of blurring of the image increases not only in the center of the imaging region FOV but also in the edge.

FIG. 2B shows an example of sharpness distributions SP1 to SP4 of images within the imaging region (FOV) when the focal planes FP1 to FP4 are obtained. The horizontal axis of the graph in FIG. 2B indicates the horizontal position of the imaging region FOV, and the vertical axis indicates the sharpness. As the sharpness decreases, the image gets sharper.

The sharpness distribution SP is a downwardly convex curve (sharpness is small near the center) in an overfocus state (focal plane FP1, and the like) (curves SP1 and SP2), and is an upwardly convex curve (sharpness is large near the center) in the underfocus state (focal planes FP3 and FP4) (curves SP3 and SP4). The degree of bending of the curve of the sharpness distribution also increases to the extent that the focal plane FP moves away from the surface of the sample 12 according to the change in the degree of curvature of field. Therefore, by detecting the direction and degree of bending of the sharpness distribution, it is possible to determine the shift amount and the shift direction of the focus position.

In the first embodiment, as shown in FIG. 2C, data of a sharpness difference ΔS between the center and the edge in the imaging region FOV is stored in the database 15, and the sharpness difference ΔS within the imaging region FOV of the actually imaged image is calculated and compared with the data in the database 15. As a result, it is possible to determine the shift amount and the shift direction of the current focus position from the surface position of the sample 12. By adding the shift amount to the current focus position, it is possible to align to the optimum focus position with a small number of operations. As a result, in the autofocus operation, the focus sweep operation is unnecessary or the number of executions thereof can be reduced, enabling high-speed autofocus operation. Since the focus sweep operation is unnecessary or the number of executions thereof is reduced, charging of the sample 12 can be prevented, and damage such as contamination and shrinkage of the sample 12 can be prevented.

When collecting and storing the data to be stored in the database 15, it is possible to shorten the calculation processing time and the imaging time by narrowing down the data acquisition target to the area where the curvature of field characteristic can be measured.

The procedure of executing the high-speed autofocus operation in the charged particle beam device of the first embodiment will be described with reference to the flowchart of FIG. 2D. First, in step S1, after setting a variable i indicating the number of repetitions of the autofocus operation to 0 (step S1), the sample 12 is moved to the imaging region FOV (step S2), and an image of the imaging region FOV is acquired (step S3). Then, the sharpness distribution of the imaging region FOV is calculated (step S4). The obtained sharpness distribution is compared with the data in the database 15, and a shift amount ΔF and the shift direction of the focus position are calculated (step S5).

When the shift amount ΔF of the focus position is obtained, the comparison operation unit 16 determines whether the number of repetitions i of the autofocus operation is greater than 0 (i>0) and the shift amount ΔF is equal to or less than the threshold (step S6). When the determination is affirmative (YES), the autofocus operation ends (END). On the other hand, when the determination is negative (NO), the process proceeds to step S7, where the shift amount ΔF is superimposed on the current focus position to bring the focus position closer to the optimum focus position. In step S8, it is determined whether confirming the optimum focus is necessary, and when it is determined necessary (YES), 1 is added to the variable i, the process returns to step S3, and steps S3 to S6 are repeated again. When the optimum focus confirmation is not necessary (NO), the autofocus operation ends (END).

A sharpness S of the image is affected by observation conditions such as characteristics of the sample 12 (for example, material, pattern geometry, roughness, and the like) within the imaging region FOV and characteristics of the electron beam optical system. Therefore, the relation between the focus position and the sharpness difference ΔS varies according to the combination of the observation conditions. According to the observation conditions, there may be concerns about the effect on the accuracy of autofocus operation. Therefore, in addition to the data of the sharpness difference ΔS, the data such as the characteristics of the sample 12 and the characteristics of the electron beam optical system may be stored in the database 15 of the present embodiment, thereby correcting the data of the sharpness difference.

In the present embodiment, the sharpness difference ΔS is extracted and used as an example of the feature amount used for high-speed autofocus operation, but the sharpness difference ΔS is merely an example of the feature amount of the image, and is not limited thereto. For example, instead of the sharpness difference ΔS, a contrast of the image and a differential value of the image may be calculated as the feature amounts and stored in the database. It is also possible to calculate a correlation operation (for example, a convolution operation using a convolution neural network or the like) for an image during optimal focus, or calculate a difference between images. The data stored in the database 15 may be in the form of a function or graph in which the focus position and the sharpness difference ΔS are associated one-to-one as shown in FIG. 2C, or may be in a form in which the sharpness is stored in a matrix for each small area within the imaging region FOV as shown in FIGS. 2E to 2G. When there is concern about focus errors due to the discrete focus positions of the data to be stored, it is also possible to perform interpolation processing in the height direction on the stored data.

### Second Embodiment

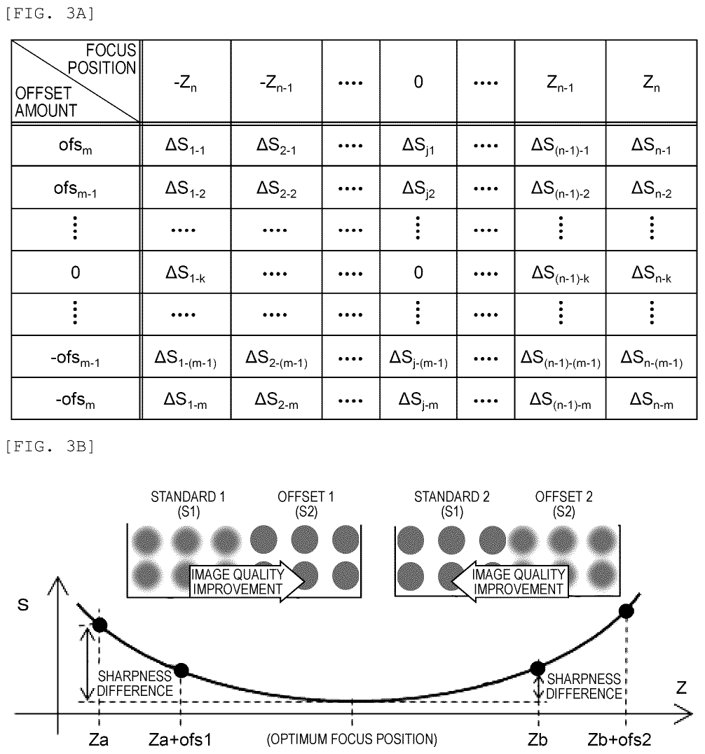

Next, a charged particle beam device according to the second embodiment of the present disclosure will be described with reference to FIGS. 3A to 3C. Since the overall configuration of the charged particle beam device of the second embodiment is substantially the same as that of the first embodiment, duplicate description will be omitted below. The second embodiment differs from the first embodiment in the method of executing the high-speed autofocus operation. The data for the autofocus operation stored in the database 15 is different from that in the first embodiment.

An example of the data stored in the database for autofocus operation in the charged particle beam device of the second embodiment will be described with reference to FIG. 3A. FIG. 3A shows the relation between a focus position Z of the primary electron beam 6, an offset amount ofs when the focus position is further moved from the focus position Z, and a sharpness difference ΔS, which is a difference between the sharpness of the image at the focus position Z and the sharpness of the image at the offset position. As described with reference to FIG. 2B, since the sharpness of the image and the curvature of the focal plane differ according to the focus position, the sharpness difference ΔS when the offset is applied differs according to the focus position and the offset amount from the same. Therefore, in the second embodiment, the relation between the focus position Z, the offset amount ofs, and the sharpness difference ΔS is stored in the database 15.

FIG. 3B shows a principle of the autofocus operation in the second embodiment. The horizontal axis of FIG. 3 indicates the focus position Z of the primary electron beam 6, and the vertical axis indicates the sharpness S of the image imaged at the focus position. The sharpness S is the smallest at the optimum focus position (0), and the sharpness S increases as the distance from the optimum focus position increases.

The data as shown in FIG. 3A is stored in the database 15 in advance, and as shown in FIG. 3B, an image of the sample 12 is imaged at a certain focus position Za, and a sharpness S1 at a predetermined position of the image is calculated. Next, the focus position is shifted from the position by a predetermined offset amount ofs1, the image of the sample 12 is imaged again at the offset position Zatofs1, and a sharpness S2 at the predetermined position of the image is calculated. Then, the sharpness difference ΔS, which is the difference between the sharpness S1 and the sharpness S2, is calculated.

The comparison operation unit 16 refers to the offset amount ofs and the obtained sharpness difference ΔS in the database 15, and calculates the shift amount ΔF and the shift direction of the focus position based on the database 15. As a result of comparing the sharpness S1 and the sharpness S2, when S2 is less than S1 (when the sharpness difference ΔS is a negative value), it means that the focus position is moved by the offset amount closer to the optimum focus position. Conversely, when S2 is greater than S1 (when the sharpness difference ΔS is a positive value), it means that the focus position is moved by the offset amount further away from the optimum focus position. By referring to the database 15 with the obtained offset amount and the sharpness difference ΔS, it is possible to know the shift amount ΔF and the shift direction of the focus position.

The procedure of executing the high-speed autofocus operation in the charged particle beam device of the second embodiment will be described with reference to the flowchart of FIG. 3C. First, in step S1, after setting a variable i indicating the number of repetitions of the autofocus operation to 0 (step S1), the sample 12 is moved to the imaging region FOV (step S2), and an image 1 of the imaging region FOV is acquired (Step S3-1). Then, the focus position is moved from the focus position of image 1 by a predetermined offset amount ofs1 (step S3-2), and an image 2 of the imaging region FOV is acquired (step S3-3). Then, the sharpness distribution of the imaging regions FOV of the images 1 and 2 is calculated (step S4). The obtained sharpness distribution of the images 1 and 2 is compared with the data in the database 15, and the shift amount ΔF and the shift direction of the focus position are calculated (step S5′).

When the shift amount ΔF of the focus position is obtained, the comparison operation unit 16 determines whether the number of repetitions i of the autofocus operation is greater than 0 (i>0) and the shift amount ΔF is equal to or less than the threshold (step S6). When the determination is affirmative (YES), the autofocus operation ends (END). On the other hand, when the determination is negative (NO), the process proceeds to step S7, where the shift amount ΔF is superimposed on the current focus position to bring the focus position closer to the optimum focus position. In step S8, it is determined whether confirming the optimum focus is necessary, and when it is determined necessary (YES), 1 is added to the variable i, the process returns to step S3-1, and steps S3-1 to S6 are repeated again. When the optimum focus confirmation is not necessary (NO), the autofocus operation ends (END).

According to the second embodiment, as in the first embodiment, high-speed autofocus operation can be performed according to the data stored in the database 15. In the first embodiment, since the shift amount ΔF and the shift direction of the focus position are determined based on the sharpness difference ΔS in one image, it is suitable for autofocus operation of a wide-field image (low-magnification image). Meanwhile, in the second embodiment, the shift amount ΔF and the shift direction of the focus position are determined based on the sharpness difference at predetermined positions of a plurality of images at positions shifted by the offset amount. Therefore, the target of the autofocus operation may include not only the wide-field images but also narrow-field images (high-magnification images). The second embodiment is also effective when it is desired to observe a fine pattern in a narrow imaging area under a very small pixel or for a rough pattern with no sensitivity to image surface characteristics.

### Third Embodiment

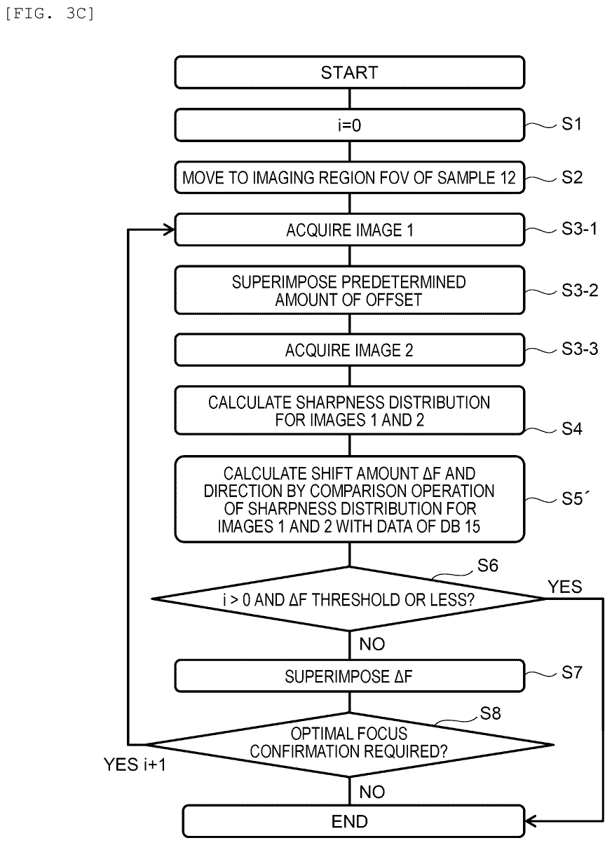

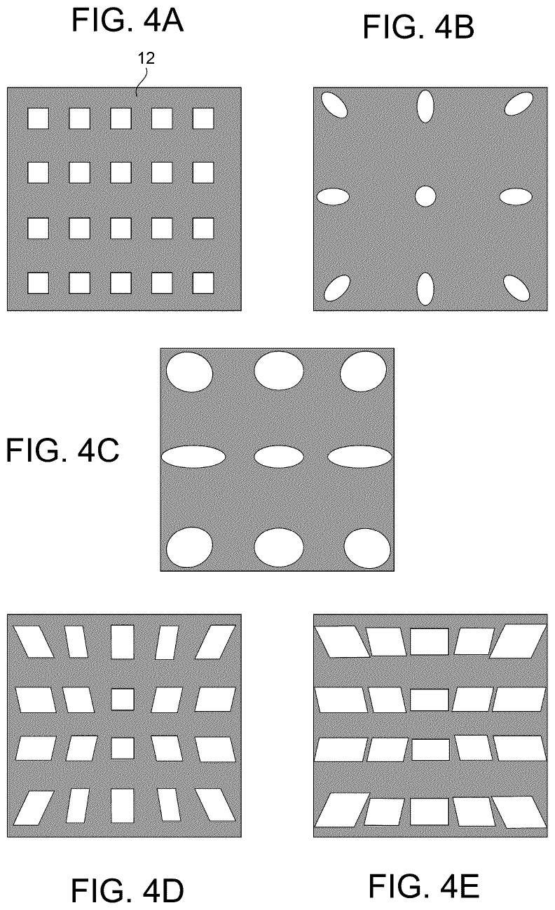

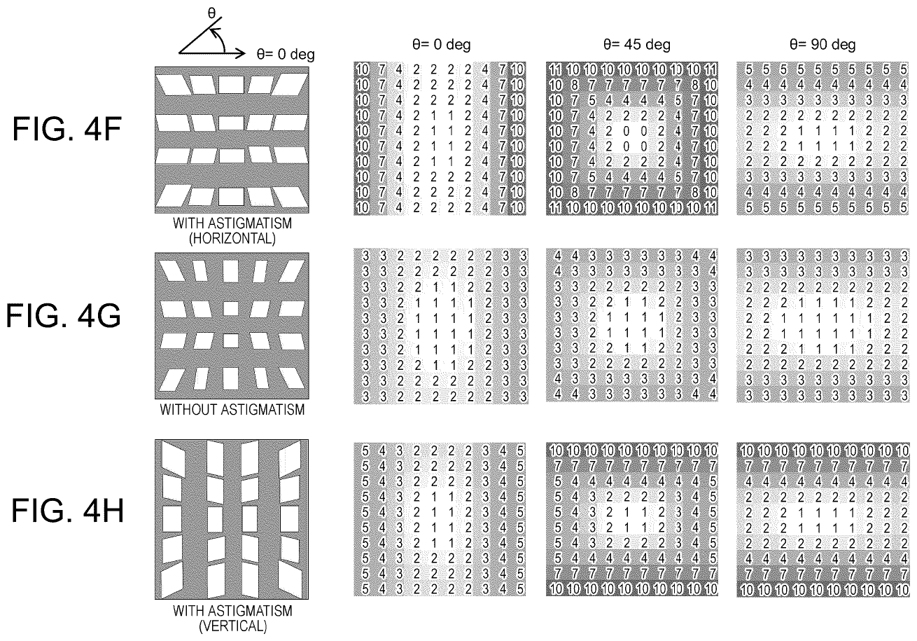

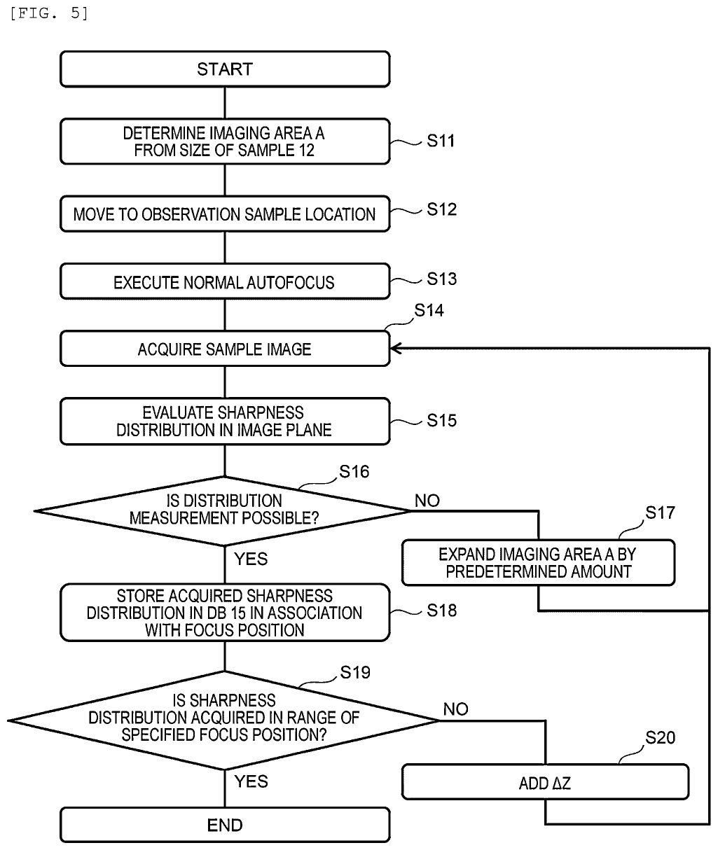

Next, a charged particle beam device according to the third embodiment of the present disclosure will be described with reference to FIG. 4A. Since the overall configuration of the charged particle beam device of the third embodiment is substantially the same as that of the first embodiment, duplicate description will be omitted below. The third embodiment differs from the first embodiment in the method of executing the high-speed autofocus operation. The data for the autofocus operation stored in the database 15 is different from that in the first embodiment. Specifically, the third embodiment is configured such that, in addition to storing the data for the focus position adjustment in the database 15, data for astigmatism adjustment is stored in the database 15 to perform astigmatism correction.

An example of the data stored in the database 15 for astigmatism adjustment in the charged particle beam device of the third embodiment will be described with reference to FIG. 4A. The charged particle beam device of the third embodiment stores, in the database 15, a pattern shape of the sample 12 (FIG. 4A), an electron beam shape distribution when the electron optical system has no astigmatism (FIG. 4B), an electron beam shape distribution with astigmatism (FIG. 4C), the image of the sample 12 imaged by the electron beam having the beam shape distribution of FIG. 4B (FIG. 4D), and the image of the sample 12 imaged by the electron beam having the beam shape distribution of FIG. 4C (FIG. 4E).

When imaging one sample, as the shape of the electron beam projected onto the sample changes due to astigmatism, the obtained image of the sample also changes. The image of the sample 12 shown in FIG. 4D or 4E may be obtained by a convolution operation of the pattern shape of the sample 12 (FIG. 4A) and the electron beam shape distribution (FIG. 4B or 4C). In the third embodiment, images such as those shown in FIGS. 4A to 4E and/or feature amounts (sharpness, and the like) of the images are stored in the database 15. The astigmatism of the electron optical system may be calculated by referring to the database 15 based on the actually imaged image of the sample 12 or the feature amount thereof. The control unit 21 controls the astigmatism adjustment coil 8 according to the calculated astigmatism, thereby correcting the astigmatism of the electron optical system and eliminating the image astigmatism.

FIGS. 4F to 4H are examples of data for astigmatism adjustment stored in the database 15 in the third embodiment. Since sharpness deterioration occurs in the direction of astigmatism, the sharpness distribution during occurrence of astigmatism is stored as sharpness distribution data for each azimuth angle θ. The data sets are desirably a combination of numerical values uniquely determined with respect to the focus height position, and any index value (for example, contrast, shading, and the like) relating to image quality that satisfies the conditions may be applied.

Although the present embodiment describes the case of adjusting astigmatism, in addition to astigmatism, it is also possible to store data related to optic axis misalignment in the database 15 and simultaneously perform automatic correction of the optic axis misalignment. Utilizing the fact that the beam shape distribution within the imaging region FOV changes due to the aberration (curvature of field, distortion, coma, astigmatism, chromatic aberration, and the like) caused by the optic axis misalignment, it is possible to adjust the optic axis at high speed by constructing the database 15 with a similar scheme. According to the present embodiment, the related search flow for finding the optimum point by measuring changes in astigmatism (and optic axis misalignment) while changing the set voltage of the astigmatism adjustment coil 8 (the optic axis adjustment coil 9) is no longer required, making it possible to speed up and reduce damage.

### Fourth Embodiment

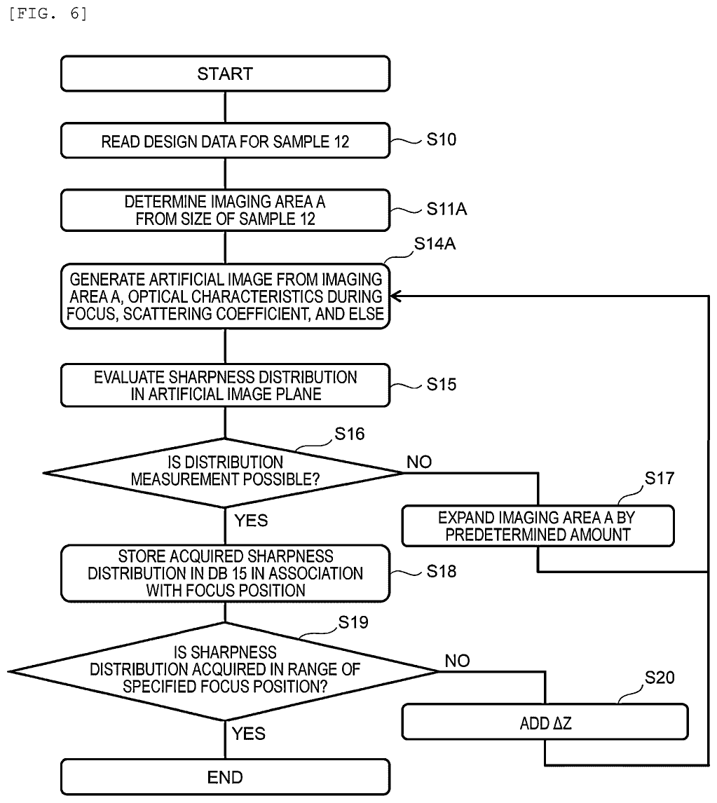

Next, a charged particle beam device according to the fourth embodiment of the present disclosure will be described with reference to FIG. 5. As in the first embodiment, the charged particle beam device of the fourth embodiment stores data on the sharpness difference in one image in the database 15, calculates the sharpness difference in the image of the sample 12 obtained by the autofocus operation, and refers to the database 15 to calculate the shift amount and the shift direction of the focus position. The fourth embodiment is characterized by the procedure of imaging an image of an actual sample 12, acquiring data on the sharpness difference of the image, and storing the data in the database 15. Since the overall configuration of the device is substantially the same as that of the first embodiment (FIG. 1), duplicate description will be omitted below.

A procedure for acquiring data on the sharpness difference to be stored in the database 15 will be described with reference to the flowchart of FIG. 5. First, the control unit 21 acquires information on the size of the sample 12 to be observed, and determines an area A of the imaging region based on the size (step S11).

Subsequently, the area A of the imaging region FOV is determined from the size of the sample 12 (step S11). Then, moving to the imaging region FOV of the sample 12, the autofocus operation is performed, acquiring an image at the optimum focus in the determined imaging area A (steps S12 and S13). Then, the sharpness distribution within the acquired imaging region FOV is calculated and evaluated (step S15).

Subsequently, it is determined whether the sharpness distribution can be measured (step S16). For data to be stored in the database 15, a necessary condition is that the focal plane FP has a predetermined curvature of field within the imaging region FOV, and as a result, the imaging region FOV has a predetermined sharpness distribution, which can be quantitatively measured. Therefore, when the sharpness distribution cannot be measured, the imaging area A is widened by a predetermined amount and the image of the sample 12 is acquired again, and the step is repeated until the sharpness distribution can be measured (step S17). When the sharpness distribution can be measured, the measured sharpness distribution is stored in the database 15 in association with the focus position (step S18).

Next, it is determined whether the acquisition of the sharpness distribution within a range of a predetermined focus position is completed (step S19). If YES, the flow of FIG. 5 ends. If NO, the focus position is added by a predetermined amount ΔZ, and the image of the sample 12 is acquired again at the position (step S14). Then, similar operations are repeated until a YES determination is obtained in step S19. Note that the magnitude of ΔZ may be determined according to the amount of defocus that may occur in the actual usage environment of the charged particle beam device, or may be determined according to the physical positioning accuracy of the stage when the stage is moved with respect to the registered coordinates, or may be determined considering various other factors.

### Fifth Embodiment

Next, a charged particle beam device according to the fifth embodiment of the present disclosure will be described with reference to FIG. 6. As in the first embodiment, the charged particle beam device of the fifth embodiment stores data on the sharpness difference in one image in the database 15, calculates the sharpness difference in the image of the sample 12 obtained by the autofocus operation, and refers to the database 15 to calculate the shift amount and the shift direction of the focus position. The fifth embodiment is characterized by the procedure of reading a design data of the sample 12, acquiring the data of the sharpness difference of an obtained artificial image, and storing the data in the database 15. Since the overall configuration of the device is substantially the same as that of the first embodiment (FIG. 1), duplicate description will be omitted below.

A procedure for acquiring data on the sharpness difference to be stored in the database 15 according to the design data will be described with reference to the flowchart of FIG. 6. First, the control unit 21 reads the design data of the sample 12 to be observed (step S10), and determines the area A of the imaging region based on the size of the sample 12 (step S11A).

Subsequently, the area A of the imaging region FOV is determined from the size of the sample 12 (step S11A). Then, an artificial image is generated based on the design data from the area A of the imaging region FOV, the optical characteristics (irradiation voltage, probe current, detection rate, and the like) of the electron optical system at the optimum focus position (in-focus state), the shape, material, scattering coefficient, of the surface of the sample 12, and the like (step S14A). Then, the sharpness distribution in the acquired artificial image is calculated and evaluated (step S15).

Subsequently, it is determined whether the sharpness distribution can be measured (step S16). For data to be stored in the database 15, a necessary condition is that the focal plane FP has a predetermined curvature of field within the imaging region FOV, and as a result, the imaging region FOV has a predetermined sharpness distribution, which can be quantitatively measured. Therefore, when the sharpness distribution cannot be measured, the imaging area A is widened by a predetermined amount and the image of the sample 12 is acquired again, and the step is repeated until the sharpness distribution can be measured (step S17). When the sharpness distribution can be measured, the measured sharpness distribution is stored in the database 15 in association with the focus position (step S18).

Next, it is determined whether the acquisition of the sharpness distribution within a range of a predetermined focus position is completed (step S19). If YES, the flow of FIG. 5 ends. If NO, the focus position is added by a predetermined amount ΔZ, and the image of the sample 12 is acquired again at the position (step S14). Then, similar operations are repeated until a YES determination is obtained in step S19.

In the embodiment, since the data stored in the database 15 is generated according to the artificial image, it is not necessary to image the sample 12 directly, so damage to the sample 12 can be reduced, and the machine time of the device, the time for which the sample is occupied, and the like can be shortened.

### Sixth Embodiment

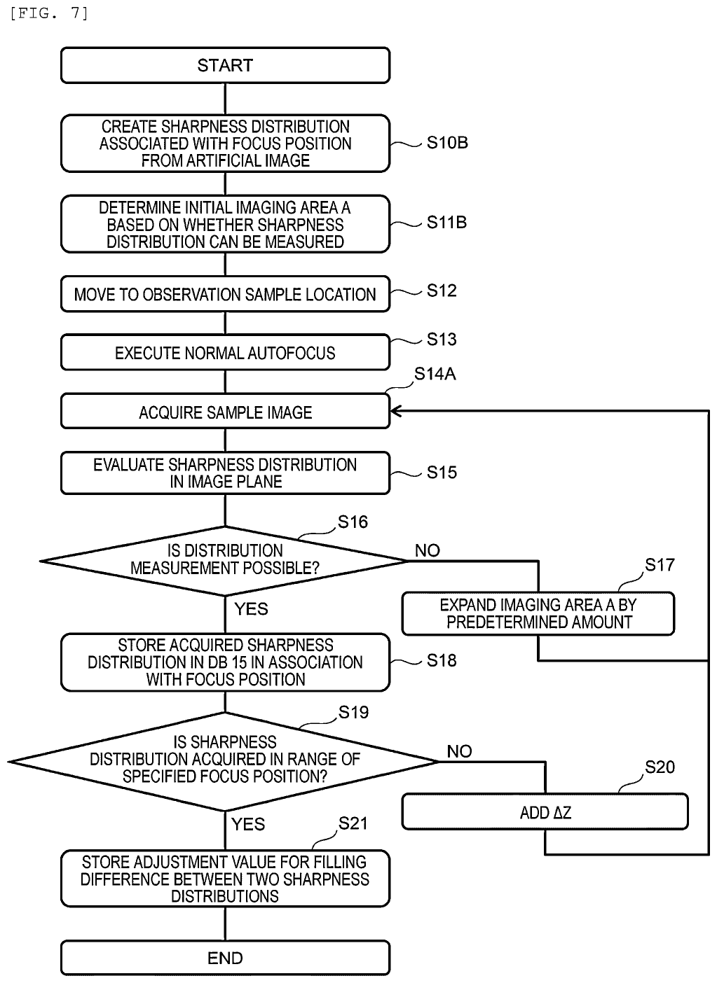

Next, a charged particle beam device according to the sixth embodiment of the present disclosure will be described with reference to FIG. 7. As in the first embodiment, the charged particle beam device of the sixth embodiment stores data on the sharpness difference in one image in the database 15, calculates the sharpness difference in the image of the sample 12 obtained by the autofocus operation, and refers to the database 15 to calculate the shift amount and the shift direction of the focus position. In the sixth embodiment, the actual sample 12 is imaged, the design data of the sample 12 is also read, the data of the sharpness difference between the image of the actual sample 12 and the artificial image is acquired, the sharpness difference is adjusted considering the difference and ratio, and the result is stored in the database 15. Using both the real image and the artificial image, it is possible to store data in the database 15 with higher accuracy. Since the overall configuration of the device is substantially the same as that of the first embodiment (FIG. 1), duplicate description will be omitted below.

A procedure for acquiring data on the sharpness difference to be stored in the database 15 will be described with reference to the flowchart of FIG. 7. First, after acquiring an artificial image in the same manner as in the fifth embodiment, the control unit 21 acquires data on the sharpness distribution associated with the focus position based on the artificial image, and stores the data in the database 15 (step S10B). Subsequently, it is determined whether the sharpness distribution can be measured, the imaging area A of the initial imaging region FOV is determined according to the determination result (step S11B). After moving to the imaging region FOV (step S12), the normal autofocus operation is performed to acquire an image of the sample 12 (step S14A).

After the image of the sample 12 is obtained, the sharpness distribution in the image is acquired and evaluated (step S15). When the sharpness distribution cannot be measured, the imaging area A is widened by a predetermined amount and the image of the sample 12 is acquired again, and the step is repeated until the sharpness distribution can be measured (step S17). When the sharpness distribution can be measured, the measured sharpness distribution is stored in the database 15 in association with the focus position (step S18).

Next, it is determined whether the acquisition of the sharpness distribution within a range of a predetermined focus position is completed (step S19). If YES, the process proceeds to step S21. If NO, the focus position is added by a predetermined amount ΔZ, and the image of the sample 12 is acquired again at the position (step S14). Then, similar operations are repeated until a YES determination is obtained in step S19.

As such, the sharpness distribution based on the artificial image is obtained in step S10B, and also the sharpness distribution based on the image of the actual sample is obtained in step S18. In step S19, an adjustment value for filling the difference between the two types of sharpness distributions is calculated and stored in the database 15.

As described above, in the sixth embodiment, the data of the sharpness difference between the image of the actual sample 12 and the artificial image is acquired, the sharpness difference is adjusted considering the difference and ratio, and the result is stored in the database 15. When the change in sharpness distribution when the focus position changes can be reproduced approximately accurately with an artificial image, the analysis of the image of the actual sample 12 may be performed to the extent of filling the peeled portion. Therefore, compared to the case of constructing the database 15 only with the images of the actual sample 12, the number of images of the sample 12 can be reduced, the procedure can be simplified, and as a result, the startup period of the charged particle beam device can be shortened. Compared to the case of constructing the database only with artificial images, it is possible to reduce the performance difference between devices and improve the accuracy of the devices. According to the embodiment, it is possible to manage the difference in performance between a plurality of devices or analyze the variations in performance.

### Seventh Embodiment

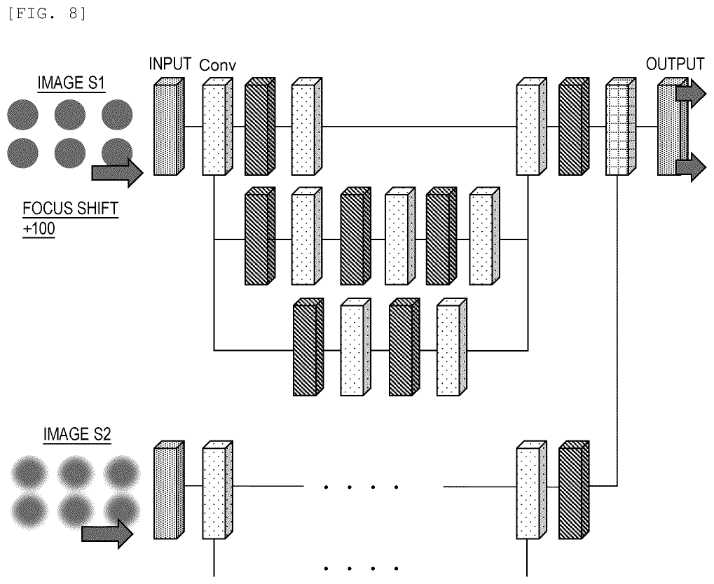

Next, a charged particle beam device according to the seventh embodiment of the present disclosure will be described with reference to FIG. 8. Since the overall configuration of the charged particle beam device of the seventh embodiment is substantially the same as that of the first embodiment, duplicate description will be omitted below. In the seventh embodiment, as in the second embodiment, the shift amount ΔF and the shift direction of the focus position are determined based on the sharpness difference at predetermined positions of a plurality of images at positions shifted by the offset amount (see FIGS. 3A and 3B). However, in the seventh embodiment, the comparison operation unit 16 is provided with a convolution network as shown in FIG. 8 to analyze the sharpness difference between an image S1 at a certain focus position and an offset image S2 at a position shifted by the offset amount, and calculate the shift amount and the shift direction of the focus position according to the analysis results. The convolutional network shown in FIG. 8 is the well-known UNET, but is not limited thereto.

For training UNET, as labeled training data, the image S1 imaged at the certain focus position and the image S2 imaged at the position further shifted by the predetermined offset amount from the focus position are input to the comparison operation unit 16 at the same time. Here, the offset amount must be equal to the offset amount (see FIG. 3B) when actually executing the high-speed autofocus operation. The training of UNET is executed such that the amount of focus shift while imaging of the image S1 is given as a target value to be output from UNET. The combination of the image S1 of the sample 12 at the certain focus position, the image S2 at the position shifted by the predetermined offset amount from the certain focus position, and the focus position Z at the image S1 is stored in the database 15 as a data set.

After training UNET, when performing a high-speed autofocus operation, as in the second embodiment, after moving to a certain imaging region FOV, an image of the sample 12 at the certain focus position is imaged under the same imaging conditions (for example, pixel size, optical conditions, and the like) as during the training to obtain the image S1. The offset amount given during training is added to the current focus position, and the image of the sample 12 is imaged again to obtain the image S2. By inputting the obtained images S1 and S2 to the UNET, it is possible to calculate the defocus amount and direction when the image S1 is imaged.

### Eighth Embodiment

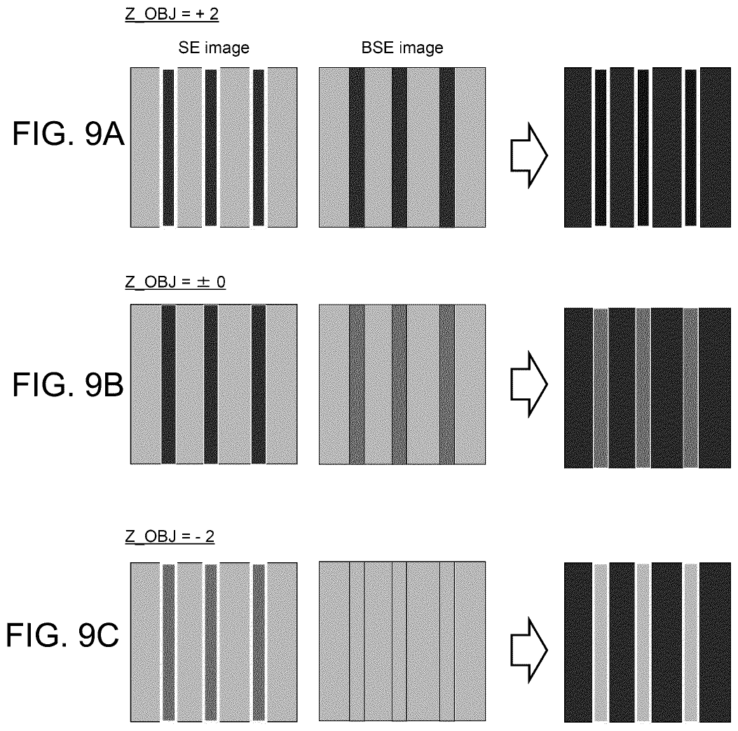

Next, a charged particle beam device according to the eighth embodiment of the present disclosure will be described with reference to FIGS. 9A to 9C. The eighth embodiment differs from the first embodiment in the method of executing the high-speed autofocus operation. The data for the autofocus operation stored in the database 15 is different from that in the first embodiment. The charged particle beam device of the ninth embodiment includes a secondary electron detector a backscattered electron detector as the detector 13, and is configured to be able to acquire a secondary electron image (SE image) and a backscattered electron image (BSE image). Since the configuration of the charged particle beam device other than the above is substantially the same as that of the first embodiment, duplicate description will be omitted below.

The high-speed autofocus operation executed based on the simultaneously acquired SE image and BSE image and the data in the database 15 in the eighth embodiment will be described with reference to FIGS. 9A to 9C. In the eighth embodiment, different types of image signals such as the SE image and the BSE image and data relating to differences in characteristics (for example, differences in brightness) of the different types of image signals are stored in the database 15 in advance, and the obtained SE image and BSE image of the sample 12 and the difference in the characteristics thereof are calculated. By comparing the difference in characteristics with the data in the database 15, it is possible to know the shift amount and the shift direction of the current focus position from the optimum focus position.

An example of data stored in the database 15 in the eighth embodiment will be described with reference to FIGS. 9A to 9C. For example, a sample to be observed in the eighth embodiment is a sample having deep grooves formed therein and having height differences on the surface, as shown in FIGS. 9A to 9C. However, aspects are not limited thereto.

In the eighth embodiment, an SE image and a BSE image are obtained for each different focus position, and also an image or data indicating the brightness difference between the two images is stored in the database 15 together with the SE image and the BSE image. For example, at the focus position Z_OBJ=±0 [a.u] (optimum focus position), the SE image is an image in which the edge of the groove on the surface of the sample 12 has a very high sharpness and a high contrast. On the other hand, the BSE image is an image in which the signal from the surface is small, the amount of signal from the bottom of the groove is relatively large, and the groove is observed brightly. Therefore, when the brightness difference between the SE image and the BSE image is referred to, the difference is apparent at the edge and the bottom of the groove. The database 15 stores a combination of the SE image and the BSE image at the focus position Z_OBJ=0, and the image or data indicating the brightness difference.

When the focus position shifts to the overfocus side, such as focus position Z_OBJ=+2 [a.u], the SE image has lower sharpness and contrast at the edge of the groove, and the bottom of the grooves is irradiated with diverging and spreading electron beams, resulting in a darker image. In the BSE image, the amount of signal similarly decreases due to the decrease in the density of electrons irradiated to the bottom of the groove. Therefore, when evaluating the brightness difference between the two images, only the edge portion is emphasized. The database 15 stores a combination of the SE image and the BSE image at the focus position Z_OBJ=+2, and the image or data indicating the brightness difference.

When the focus position shifts to the underfocus side, such as focus position Z_OBJ=−2 [a.u], the SE image remains lower in both sharpness and contrast than at the optimum focus position due to defocus at the edge of the groove, but conversely, the bottom of the groove becomes a bright image. Meanwhile, since the BSE image is irradiated with the electron beam with good convergence, the image at the edge of the groove is bright, but since the BSE image is a signal type that is less attenuated with respect to the height difference than the SE image, the image has a further remarkable increase in brightness. Taking the difference in brightness between the two images improves the visibility of the bottom of the groove compared to the other cases. The database 15 stores a combination of the SE image and the BSE image at the focus position Z_OBJ=−2, and the image or data indicating the brightness difference.

As described above, in the eighth embodiment, data of combinations of images of different kinds of signals (SE image, BSE image) acquired for each focus position and the differences in characteristics (for example, differences in brightness) thereof are stored in the database and used as reference information. In the high-speed autofocus operation, after acquiring the SE image and the BSE image of the sample 12 and calculating the difference in characteristics thereof, by referring to the database 15, it is possible to calculate the shift amount and the shift direction of the current focus position from the optimum focus position.

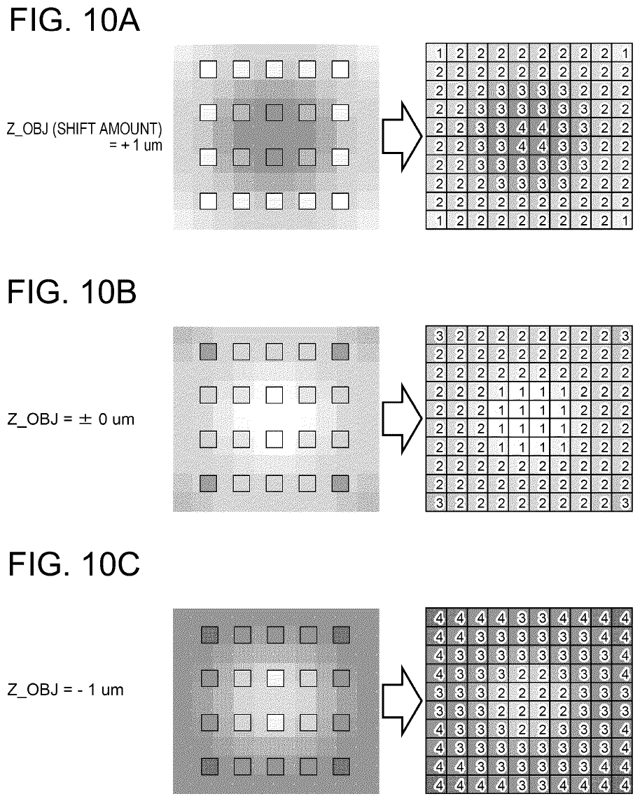

It is theoretically possible to store the differences in characteristics (for example, difference in brightness) of a plurality of SE images obtained at different focus positions or the differences in characteristics (for example, difference in brightness) of a plurality of BSE images obtained at different focus positions in the database 15, and execute the actual autofocus operation according to the differences in brightness at a plurality of focus positions. However, by calculating the shift in the focus position according to the difference in characteristics (for example, difference in brightness) between the SE image and the BSE image, an autofocus operation can be performed at higher speed and with higher precision. It is also possible to mainly use the BSE image to determine the shift direction of the focus position, such as overfocus or underfocus, and use the SE image to estimate the shift amount. The data on brightness difference to be stored in the database 15 may be obtained by storing data representing the brightness difference for each small area in the image in a matrix form for each focus position as shown in FIGS. 10A to 10C.

Note that the present disclosure is not limited to the embodiments described above, and includes various modified examples. For example, the embodiments described above are described in detail to explain the present disclosure in an easy-to-understand manner, and are not necessarily limited to those having all the configurations described above. A part of the configuration of an embodiment can be replaced with the configuration of another embodiment, and the configuration of another embodiment can be added to the configuration of an embodiment. It is possible to add, delete, and replace other configurations for a of the configuration of each embodiment. Each of the configurations, functions, processing units, processing means, and the like described above may be realized by hardware by designing a part or all of those with, for example, an integrated circuit. Each of the configurations, functions, and the like described above may be realized by software by interpreting and executing a program that realizes each function by the processor. Information such as a program, a table, a file, and the like that realizes each function may be stored in a storage device such as a memory, a hard disk, and a solid state drive (SSD), or a recording medium such as an IC card, an SD card, and DVD.

### REFERENCE SIGNS LIST

1: electron gun
2, 3: extraction electrodes
4: anode diaphragm
5: condenser lens
6: primary electron beam
7: objective variable diaphragm
8: astigmatism adjustment coil
9: optic axis adjustment coil
10: scanning polarizer
11: objective lens
12: sample
13: detector
14: signal processing unit
15: database
16: comparison operation unit
17: image generation processing unit
18: display
20: power supply
21: control unit

1.-16. (canceled)

17. A charged particle beam device comprising:
a charged particle beam optical system that converges/polarizes a charged particle beam and irradiates a sample with the charged particle beam;
an image generation processing unit that generates an image of the sample by detecting the charged particle beam;
a storage unit that stores a relation between a focus position of the charged particle beam by the charged particle beam optical system and a feature of the image of the sample;
a comparison operation unit that determines a shift amount and a shift direction of the focus position of the charged particle beam by comparing information obtained from the image generated by the image generation processing unit and information in the storage unit; and
a control unit that controls the charged particle beam optical system according to a comparison result of the comparison operation unit, wherein
the storage unit stores information relating to a sharpness difference in the image of the sample for each of the focus position of the charged particle beam as data relating to the feature of the image of the sample.

18. The charged particle beam device according to claim 17, wherein the sharpness difference is stored as a difference between a sharpness near a center of the image and a sharpness near an edge of the image.

19. The charged particle beam device according to claim 17, wherein the storage unit stores a sharpness difference between an image obtained at one focus position of the charged particle beam and an image obtained at a position shifted from the one focus position by an offset amount as data relating to the features of the image.

20. The charged particle beam device according to claim 19, wherein the control unit calculates a sharpness difference, which is a difference between a sharpness of an image obtained at one focus position of the charged particle beam and a sharpness of an image obtained at a position shifted from the one focus position by an offset amount, and specifies the shift amount and the shift direction of the focus position of the charged particle beam with reference to the storage unit according to the sharpness.

21. The charged particle beam device according to claim 17, wherein the storage unit includes data for astigmatism correction of the image as data relating to the feature of the image.

22. A charged particle beam device comprising:
a charged particle beam optical system that converges/polarizes a charged particle beam and irradiates a sample with the charged particle beam;
an image generation processing unit that generates an image of the sample by detecting the charged particle beam;
a storage unit that stores a relation between a focus position of the charged particle beam by the charged particle beam optical system and a feature of the image of the sample;
a comparison operation unit that determines a shift amount and a shift direction of the focus position of the charged particle beam by comparing information obtained from the image generated by the image generation processing unit and information in the storage unit; and
a control unit that controls the charged particle beam optical system according to a comparison result of the comparison operation unit, wherein
the storage unit stores information relating to a brightness difference in the image of the sample for each of the focus position of the charged particle beam as data relating to the feature of the image of the sample.

23. A charged particle beam device comprising:
a charged particle beam optical system that converges/polarizes a charged particle beam and irradiates a sample with the charged particle beam;
an image generation processing unit that generates an image of the sample by detecting the charged particle beam;
a storage unit that stores a relation between a focus position of the charged particle beam by the charged particle beam optical system and a feature of the image of the sample;
a comparison operation unit that determines a shift amount and a shift direction of the focus position of the charged particle beam by comparing information obtained from the image generated by the image generation processing unit and information in the storage unit; and
a control unit that controls the charged particle beam optical system according to a comparison result of the comparison operation unit, wherein
the storage unit stores information on a brightness difference between a plurality of images imaged by a plurality of types of techniques as data relating to the feature of the image of the sample.

24. A method for controlling a charged particle beam device, the method comprising:
a step of converging/polarizing a charged particle beam emitted by a charged particle beam optical system;
a step of generating an image of a sample by detecting the charged particle beam;
a step of storing a relation between a focus position of the charged particle beam and a feature of the image of the sample as a database;
a step of determining a shift amount and a shift direction of the focus position of the charged particle beam by comparing information obtained from the generated image with the stored information; and
a step of controlling the charged particle beam optical system according to a comparison result, wherein
information relating to a sharpness difference in the image of the sample for each of the focus position of the charged particle beam is stored as data relating to the feature of the image of the sample.

25. The control method according to claim 24, wherein the sharpness difference is stored as a difference between a sharpness near a center of the image and a sharpness near an edge of the image.

26. The control method according to claim 24, wherein a sharpness difference between an image obtained at one focus position of the charged particle beam and an image obtained at a position shifted from the one focus position by an offset amount is stored as data relating to the features of the image.

27. The control method according to claim 26, wherein a sharpness difference, which is a difference between a sharpness of an image obtained at one focus position of the charged particle beam and a sharpness of an image obtained at a position shifted from the one focus position by an offset amount, is calculated and the shift amount and the shift direction of the focus position of the charged particle beam are specified with reference to the database according to the sharpness.

28. The control method according to claim 24, wherein the database includes data for astigmatism correction of the image as data relating to the feature of the image.

29. A method for controlling a charged particle beam device, the method comprising:
a step of converging/polarizing a charged particle beam emitted by a charged particle beam optical system;
a step of generating an image of a sample by detecting the charged particle beam;
a step of storing a relation between a focus position of the charged particle beam and a feature of the image of the sample as a database;
a step of determining a shift amount and a shift direction of the focus position of the charged particle beam by comparing information obtained from the generated image with the stored information; and
a step of controlling the charged particle beam optical system according to a comparison result, wherein
the database stores information relating to a brightness difference in the image of the sample for each of the focus position of the charged particle beam as data relating to the feature of the image of the sample.

30. A method for controlling a charged particle beam device, the method comprising:
a step of converging/polarizing a charged particle beam emitted by a charged particle beam optical system;
a step of generating an image of a sample by detecting the charged particle beam;
a step of storing a relation between a focus position of the charged particle beam and a feature of the image of the sample as a database;
a step of determining a shift amount and a shift direction of the focus position of the charged particle beam by comparing information obtained from the generated image with the stored information; and
a step of controlling the charged particle beam optical system according to a comparison result, wherein
the database stores information on a brightness difference between a plurality of images imaged by a plurality of types of techniques as data relating to the feature of the image of the sample.
